(19) United States
(12) Patent Application Publication
(10) Pub. No.: US 2023/0124931 A1
(43) Pub. Date: Apr. 20, 2023

(54) CONFIGURABLE CAPACITOR

(71) Applicant: Empower Semiconductor, Inc., Milpitas, CA (US)

(72) Inventors: Parag Oak, Sunnyvale, CA (US); Timothy Alan Phillips, Hope, RI (US); Trey Roessig, Palo Alto, CA (US); Peter Huang, Pleasanton, CA (US); Artin Der Minassians, Oakland, CA (US)

(73) Assignee: Empower Semiconductor, Inc., Milpitas, CA (US)

(21) Appl. No.: 17/451,596

(22) Filed: Oct. 20, 2021

(51) Int. Cl. H01L 49/02

(52) U.S. Cl. CPC H01L 28/86

(57) ABSTRACT

A capacitance device includes: a semiconductor substrate; a capacitor disposed on the semiconductor substrate and including first and second positive terminals and first and second negative terminals; a passivation layer formed over the capacitor, the first and second positive terminals and the first and second negative terminals, the passivation layer defining first and second openings over the first and second positive terminals, respectively, a third opening over the first negative terminal and a fourth opening over the second negative terminal; a first metallic bump disposed on the passivation layer and including first extending portions that extend through each of the first and second openings, electrically coupling the first and second positive terminals; and a second metallic bump disposed on the passivation layer and including second extending portions that extend through each of the third and fourth openings, electrically coupling the first and second negative terminals.

### BACKGROUND

Unless otherwise indicated herein, the materials described in this section are not prior art to the claims in this application and are not admitted to be prior art by inclusion in this section.

Switching DC/DC voltage regulators, as well as other electronic circuits, use decoupling capacitors to reduce voltage ripple and noise on input and output voltage lines. Miniaturization and integration of electronic circuit components leads to need for multiple high density, small footprint capacitors. One approach has been to stack multiple discrete capacitors on a printed circuit board or integrated circuit package. This approach can result in poor overall capacitor characteristics, a larger circuit footprint, and wasted board space between the capacitors due to finite spacing rules for discrete capacitors.

### SUMMARY

Aspects of the present disclosure relate to capacitors, and more particularly, though not necessarily exclusively, configurable capacitors in an integrated package.

According to various aspects there is provided a capacitance device. In some aspects, the capacitance device may include: a semiconductor substrate; a capacitor disposed on the semiconductor substrate, the capacitor including first and second positive terminals and first and second negative terminals; a passivation layer formed over the capacitor, the first and second positive terminals and the first and second negative terminals, the passivation layer defining a first opening over the first positive terminal, a second opening over the second positive terminal, a third opening over the first negative terminal and a fourth opening over the second negative terminal; a first metallic bump disposed on the passivation layer and including first extending portions that extend through each of the first and second openings, electrically coupling the first positive terminal to the second positive terminal; and a second metallic bump disposed on the passivation layer and including second extending portions that extend through each of the third and fourth openings, electrically coupling the first negative terminal to the second negative terminal.

According to various aspects there is provided a device. In some aspects, the device may include: a semiconductor substrate; a first capacitor disposed on the semiconductor substrate and electrically coupled between a first pair of metallic terminals and a second pair of metallic terminals, wherein the first and second pairs of metallic terminals are disposed on a first surface of the semiconductor substrate; a second capacitor disposed on the semiconductor substrate and electrically coupled between a third pair of metallic terminals and a fourth pair of metallic terminals, wherein the third and fourth pairs of metallic terminals are disposed on the first surface of the semiconductor substrate; a passivation layer disposed on the first surface of the semiconductor substrate and extending across at least the first, second, third and fourth pairs of metallic terminals; a pair of first openings defined by the passivation layer and a respective opening of the pair of first openings arranged over each of the pair of first metallic terminals; a pair of second openings defined by the passivation layer and a respective opening of the pair of second openings arranged over each of the pair of second metallic terminals; a pair of third openings defined by the passivation layer and a respective opening of the pair of third openings arranged over each of the pair of third metallic terminals; a pair of fourth openings defined by the passivation layer and a respective opening of the pair of fourth openings arranged over each of the pair of fourth metallic terminals; a first metallic bump disposed on the passivation layer and electrically coupling the pair of first metallic terminals together through the pair of first openings; a second metallic bump disposed on the passivation layer and electrically coupling the pair of second metallic terminals together through the pair of second openings; a third metallic bump disposed on the passivation layer and electrically coupling the pair of third metallic terminals together through the pair of third openings; and a fourth metallic bump disposed on the passivation layer and electrically coupling the pair of fourth metallic terminals together through the pair of fourth openings.

According to various aspects there is provided a device. In some aspects, device may include: a semiconductor substrate; a first capacitor disposed on the semiconductor substrate and electrically coupled between a first terminal and a second terminal; a second capacitor disposed on the semiconductor substrate and electrically coupled between a third terminal and a fourth terminal; a passivation layer disposed across a first surface of the semiconductor substrate and defining a first opening formed over the first terminal, a second opening formed over the second terminal, a third opening formed over the third terminal and a fourth opening formed over the fourth terminal; a first metallic bump disposed on the passivation layer and electrically coupled to the first terminal and the third terminal through the first and the third openings, respectively; and a second metallic bump disposed on the passivation layer and electrically coupled to the second terminal and the fourth terminal through the second and the fourth openings, respectively.

### BRIEF DESCRIPTION OF THE DRAWINGS

Various embodiments in accordance with the present disclosure will be described with reference to the drawings, in which:

FIG. 1A is a diagram illustrating a representative example of a configurable capacitance chip according to some aspects of the present disclosure;

FIG. 1B is a diagram illustrating a side view of the representative example of the configurable capacitance chip in FIG. 1A according to some aspects of the present disclosure.

FIG. 1C is a diagram illustrating a side view of another representative example of a configurable capacitance chip according to some aspects of the present disclosure.

FIG. 2 is a diagram illustrating another representative example of a configurable capacitance chip according to some aspects of the present disclosure;

FIG. 3A is a diagram illustrating a representative example of a configurable capacitance chip having a sense terminal according to some aspects of the present disclosure;

FIG. 3B is a simplified schematic diagram illustrating an electrical connection of the sense terminal internal to the configurable capacitance chip in FIG. 3A according to some aspects of the present disclosure;

FIG. 4 is a diagram illustrating an example of a configurable capacitance chip within an electronic package according to some aspects of the present disclosure;

FIG. 5 is a simplified schematic diagram illustrating example circuit connections for an application of a configurable capacitance chip according to some aspects of the present disclosure;

FIG. 6 is a simplified schematic diagram illustrating an example of some parasitic inductances of an electronic package according to some aspects of the present disclosure;

FIG. 7 is a simplified schematic diagram illustrating another example of some parasitic inductances of an electronic package according to some aspects of the present disclosure;

FIG. 8 is a diagram illustrating a representative example of a configurable capacitance-inductance chip according to some aspects of the present disclosure;

FIG. 9 is a simplified schematic diagram illustrating an example application of configurable capacitance-inductance chip according to some aspects of the present disclosure;

FIG. 10 is a diagram illustrating a representative example of a configurable capacitance-resistance chip according to some aspects of the present disclosure;

FIG. 11 is a diagram illustrating a representative example of a configurable capacitance-resistance-inductance chip according to some aspects of the present disclosure;

FIG. 12 is a flowchart illustrating an example of a method for making a configurable capacitance device according to some aspects of the present disclosure;

FIG. 13 is a diagram illustrating a representative example of a configurable capacitance chip having equal cell sizes with unequal capacitance values between cells according to some aspects of the present disclosure;

FIG. 14 is a diagram illustrating a representative example of a configurable capacitance chip having unequal cell sizes with unequal capacitance values between cells according to some aspects of the present disclosure;

FIG. 15 is a diagram illustrating a representative example of a configurable capacitance chip having shared ground connections between adjacent cells according to some aspects of the present disclosure;

FIG. 16A is a diagram illustrating a representative example of a configurable capacitance chip according to some aspects of the present disclosure;

FIG. 16B is a diagram illustrating a representative example of the configurable capacitance chip of FIG. 16A showing copper pillars forming connections between a plurality of integrally formed capacitors in a cell, according to some aspects of the present disclosure;

FIG. 16C is a diagram illustrating a cross sectional view along the section line A-A of the configurable capacitance chip in FIG. 16B according to some aspects of the present disclosure;

FIG. 16D is a diagram illustrating an example of a circuit trace connecting the copper pillars together according to some aspects of the present disclosure;

FIG. 16E is a diagram illustrating an example of interconnections coupled to terminals of integrally formed capacitors of FIG. 16A according to some aspects of the present disclosure;

FIG. 16F is a diagram illustrating an example of copper pillars formed between interconnections of the configurable capacitance chip 1600 of FIG. 16E according to some aspects of the present disclosure;

FIG. 16G is a simplified schematic diagram illustrating an example of an integrally formed capacitor of FIG. 6A according to some aspects of the present disclosure; and

FIG. 17 is a flowchart illustrating an example of a method for making a configurable capacitance chip according to some aspects of the present disclosure.

### DETAILED DESCRIPTION

While certain embodiments are described, these embodiments are presented by way of example only, and are not intended to limit the scope of protection. The apparatuses, methods, and systems described herein may be embodied in a variety of other forms. Furthermore, various omissions, substitutions, and changes in the form of the example methods and systems described herein may be made without departing from the scope of protection.

Discrete capacitors may be used for a variety of applications. One such application is decoupling capacitors used to reduce voltage ripple and noise at input and output voltage lines of integrated circuits, for example, but not limited to, voltage regulators. As integrated circuits become increasingly miniaturized with circuit components being integrated on-chip, high density, small footprint capacitors with low Equivalent Series Resistance (ESR) and Equivalent Series Inductance (ESL) requirements that can be placed close to the integrated circuits are needed.

Aspects of the present disclosure may provide a method for configuring a desired amount of capacitance on a single chip. The configurable capacitance chip may be fabricated using standard semiconductor processing techniques. A configurable capacitance chip can provide flexibility and cost advantages as compared to placing multiple capacitors on a printed circuit board (PCB) or integrated circuit (IC) package. The configurable capacitance chip may be fabricated at lower cost as compared to the cost of multiple discrete capacitors, and can provide the ability to configure capacitor characteristics such as ESR and ESL at the package level. More specifically, in some embodiments a standardized capacitance chip can be used in different applications where the number and characteristics of capacitors formed by the capacitance chip are configured by changing electrical interconnects on the package substrate to which the capacitance chip is connected. In addition, the configurable capacitance chip may occupy less space on a PCB compared to discrete capacitors. The configurable capacitance chip may be applicable to any application where multiple capacitors are required.

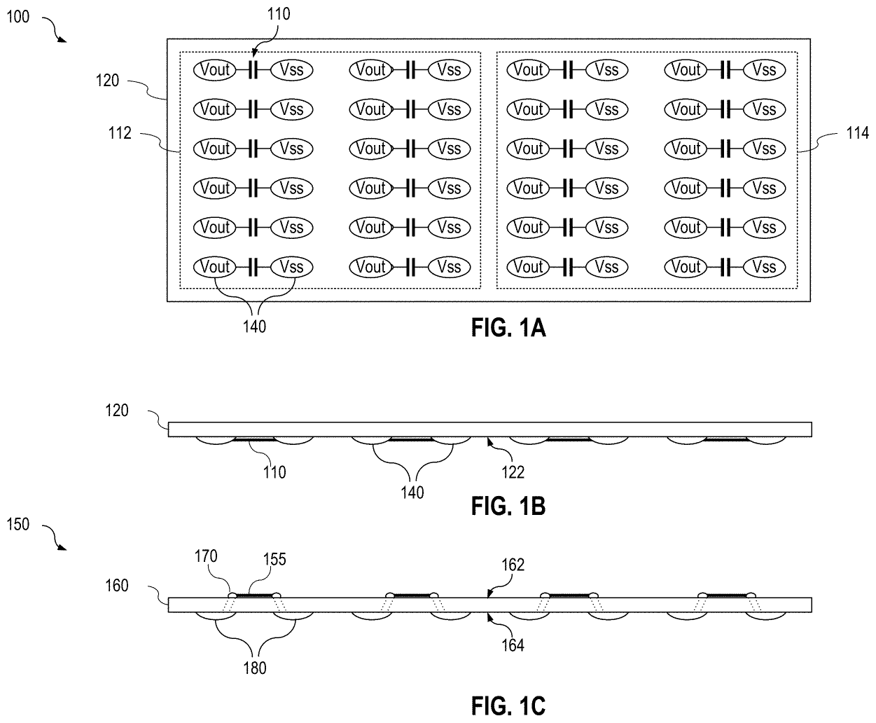

FIG. 1A is a diagram illustrating a representative example of a configurable capacitance chip 100 according to some aspects of the present disclosure. FIG. 1B is a diagram illustrating a side view of the representative example of the configurable capacitance chip 100 in FIG. 1A according to some aspects of the present disclosure. Referring to FIGS. 1A and 1B, the configurable capacitance chip 100 may include a plurality of capacitors 110 fabricated on a first surface 122 of a substrate 120. Each capacitor 110 may be electrically connected to a pair of contacts, referred to herein as chip bumps 140, fabricated on the first surface 122 of the substrate 120. The chip bumps 140 may be, for example, solder bumps.

In some embodiments, a range of capacitance for each integrated capacitor can be between 10 and 10,000 nanofarads, in another embodiment can be between 50 and 5,000 nanofarads and in one embodiment between 50 and 500 nanofarads. In some embodiments, multiple capacitors 110 may be combined to provide larger or smaller capacitance values. The combined capacitors may be referred to as capacitor banks 112, 114. The capacitor banks 112, 114 may be formed, for example, by electrical connections fabricated on the first surface 122 of the substrate 120, by electrical connections fabricated on a substrate of an IC package to which the configurable capacitance chip 100 is attached, by traces on a PCB to which the IC package is attached, or by some combination. The electrical connections may be formed to provide parallel connections of capacitors, series connections of capacitors, or series-parallel combinations of capacitors.

FIG. 1C is a diagram illustrating a side view of another representative example of a configurable capacitance chip 150 according to some aspects of the present disclosure. Referring FIG. 1C, the configurable capacitance chip 150 may include a plurality of capacitors 155 fabricated on a first surface 162 of a substrate 160. Each capacitor 155 may be electrically connected to a pair of contacts 170 fabricated on the first surface 162 of the substrate 160. The contacts 170 fabricated on the first surface 162 of the substrate 160 may be electrically connected to contacts, referred to herein as chip bumps 180, fabricated on the second surface 164 of the substrate 160. The chip bumps 180 may be, for example, solder bumps. In some embodiments, multiple capacitors 110 may be combined into banks to provide larger or smaller capacitance values by electrical connections by electrical connections fabricated on the second surface 164 of the substrate 160, by electrical connections fabricated on a substrate of an IC package to which the configurable capacitance chip 150 is attached, by traces on a PCB to which the IC package is attached, or by some combination.

While FIG. 1A illustrates two banks 112, 114 having equal numbers of capacitors in each bank, the banks may be of various sizes depending on intended applications. In some implementations, the capacitors 110 may not be grouped in banks. Electrical connections between the capacitors are not limited to the capacitors within a bank of capacitors in implementations where capacitor banks are fabricated.

It should be appreciated that FIGS. 1A, 1B, and 1C are stylized representations of the configurable capacitance chip according to some aspects of the present disclosure, and are provided for ease of explanation. The figures are not meant to illustrate representative dimensions of any elements of the configurable capacitance chip. Further, the number of illustrated capacitors is merely representative and does not limit the number of capacitors or their relative placement provided by various embodiments. In addition, while the capacitor contacts 140 are labeled Vout and Vss in FIGS. 1A, the labels are merely representative and are not to be construed as requiring the capacitor contacts 140 to be connected to Vout and Vss voltages.

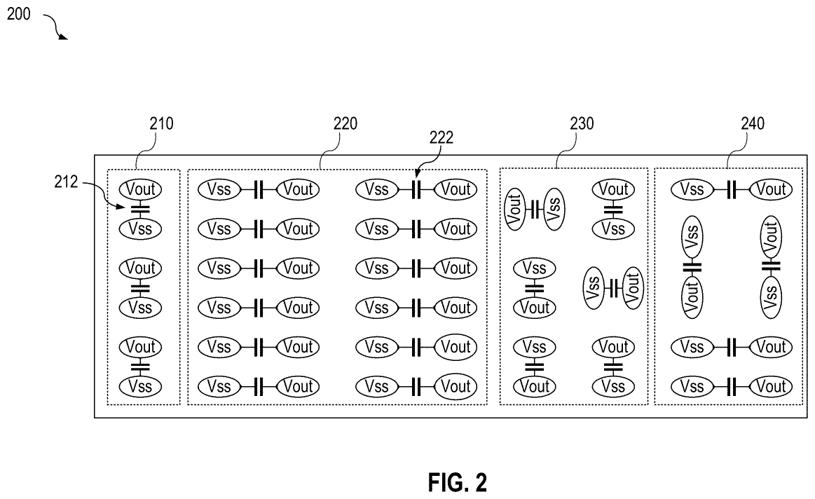

FIG. 2 is a diagram illustrating another representative example of a configurable capacitance chip 200 according to some aspects of the present disclosure. Referring to FIG. 2, the configurable capacitance chip including four different banks 210-240 of capacitors are illustrated. As shown in FIG. 2, each bank 210-240 of capacitors may include different numbers of capacitors. In addition, the capacitors may be fabricated in different orientations. For example, the capacitors 212 in the first bank 210 are fabricated in a vertical direction, while the capacitors 222 in the second bank 220 are fabricated in a horizontal direction. A capacitor bank may include capacitors fabricated in both horizontal and vertical directions. The configurable capacitance chip 200 may be configured as a single capacitor (e.g., all capacitors coupled together) or as multiple capacitors (e.g., groups of capacitors coupled together).

In some implementations, multiple configurable capacitance chips in a semiconductor package may be interconnected such that various values of capacitance can be achieved. In some implementations, multiple configurable capacitance chips may be arranged in different orientations with respect to each other in a semiconductor package. The different orientations may permit interconnection of the configurable capacitance chips such that various values of capacitance can be achieved. For example, adjacent configurable capacitance chips may be rotated to permit interconnections between the configurable capacitance chips.

It should be appreciated that FIG. 2 is a stylized representation of the configurable capacitance chip according to some aspects of the present disclosure, and is provided for ease of explanation. The figure is not meant to illustrate representative dimensions of any elements of the configurable capacitance chip. Further, the number of illustrated capacitors is merely representative and does not limit the number of capacitors or their relative placement provided by various embodiments. In addition, while the capacitor terminals are labeled Vout and Vss in FIGS. 2, the labels are merely representative and are not to be construed as requiring the capacitor terminals to be connected to Vout and Vss voltages.

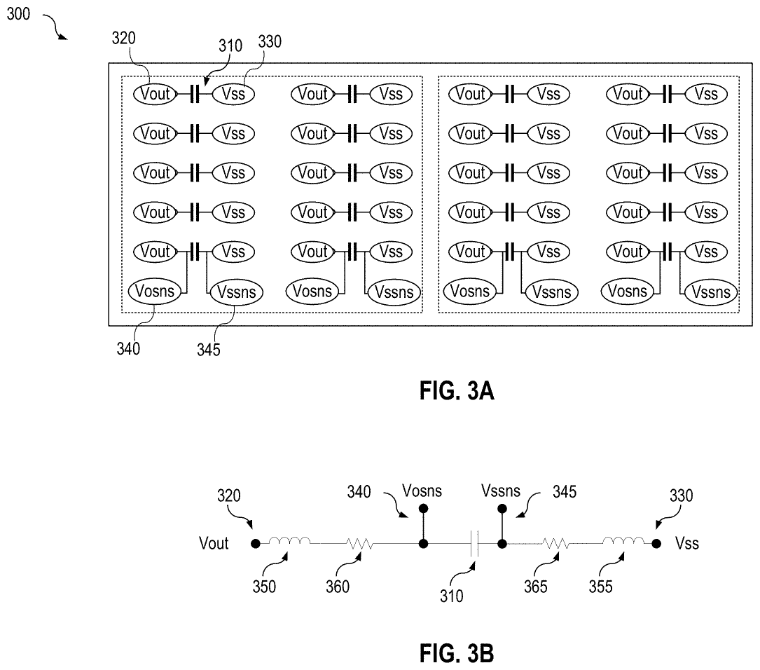

FIG. 3A is a diagram illustrating a representative example of a configurable capacitance chip 300 having a sense terminal according to some aspects of the present disclosure. FIG. 3B is a simplified schematic diagram illustrating an electrical connection of the sense terminals internal to the configurable capacitance chip 300 in FIG. 3A according to some aspects of the present disclosure. Referring to FIGS. 3A and 3B, the configurable capacitance chip 300 may include a first voltage sense terminal Vosns 340 and a second voltage sense terminal 345. The voltage sense terminal Vosns 340 may be connected externally to a solder bump (e.g., a solder bump 140) of the configurable capacitance chip 300, and internally to the configurable capacitance chip 300 at the capacitor 310 and may be a connection point of a combination of capacitors the configurable capacitance chip 300. One or more voltage sense terminal Vosns 340 solder bumps may be used per capacitor bank or group of capacitors. The voltage sense terminal Vssns 345 may be connected externally to a solder bump (e.g., a solder bump 140) of the configurable capacitance chip 300, and internally to the configurable capacitance chip 300 at the capacitor 310 and may be a connection point of a combination of capacitors the configurable capacitance chip 300. One or more voltage sense terminal Vssns 345 solder bumps may be used per capacitor bank or group of capacitors.

The voltage sense terminal Vosns 340 may enable voltage sensing that minimizes the effect of the ESR 360 and ESL 350 of the capacitor or combination of capacitors. For example, in a voltage regulator application, the voltage sense terminal Vosns 340 may minimize the effects of the parasitic resistance and inductance of the Vout configurable capacitive chip bumps, metal routing on the package (or PCB) substrates and/or Vout package balls and on the control loop of the voltage regulator. The inductors of the voltage regulator may be terminated on Vout bumps while the control loop feedback can be taken from the Vout sense bump Vosns 340. Similarly, the voltage sense terminal Vssns 345 may enable voltage sensing that minimizes the effect of the ESR 365 and ESL 355 of the capacitor or combination of capacitors.

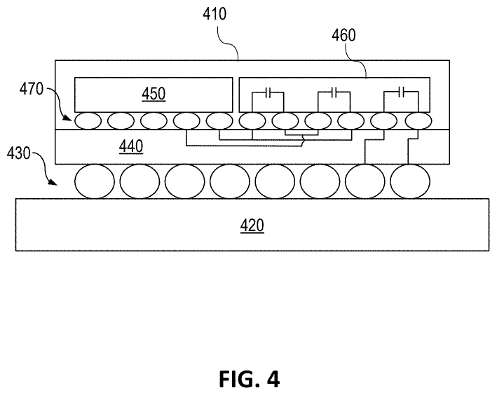

FIG. 4 is a diagram illustrating an example of a configurable capacitance chip within an electronic package according to some aspects of the present disclosure. As illustrated in FIG. 4, an electronic package 410 may be mounted on a PCB 420 with a ball grid array 430 or other solder connections connecting a package substrate 440 to the PCB 420. An integrated circuit 450, for example, a voltage regulator, and a configurable capacitance chip 460 may be mounted on the package substrate 440 within the electronic package 410 using solder bumps 470. Electrical connections between the integrated circuit 450 and the configurable capacitance chip 460 may be formed through the solder bump connections to the package substrate 440. Electrical connections between the integrated circuit 450 and electrical connections to the configurable capacitance chip 460 (e.g., Vout, Vss, Vosns) may be brought out to the PCB via the ball grid array 430 or other solder connections connecting a package substrate 440 to the PCB 420.

Electrical connections from integrated circuit 450 and the configurable capacitance chip 460 to the PCB 420 may be formed by the solder bumps 470 and the ball grid array 430. In some implementations, electrical connections between the capacitors on the configurable capacitance chip 460 may be fabricated on the substrate of the configurable capacitance chip 460, on a substrate 440 of the electronic package 410 to which the configurable capacitance chip 460 is attached, by traces on a PCB 420 to which the electronic package 410 is attached, or by some combination of the electrical connections.

As used herein, the terms “ball” or “package ball” may refer to an electrical connection (e.g., balls 430) between an integrated circuit package, for example, but not limited to, Quad Flat No-lead (QFN) packages, quad flat packs (QFPs), small outline ICs (SOICs), or other types of electronic packages, and a PCB. As used herein, the terms “bump” or “chip bump” may refer to a solder bump connection (e.g., bumps 470) between an integrated circuit chip 450 or configurable capacitance chip 460 and an electronic package substrate 440, or in a chip on board (COB) implementation, between the integrated circuit or configurable capacitance chip and the PCB 420.

Either the substrate 440 of the electronic package 410, the PCB 420, or both, can be used to connect any number of the chip capacitors together to form one or more capacitors having a particular capacitance, ESR and ESL value. By changing the electrical traces on either structure from application to application, a standardized capacitor chip can be configured for multiple applications. For example, in one application, all of the capacitors can be coupled in parallel to provide one large capacitor. In another application, one capacitor may be used for an IC decoupling capacitor, a first group of 10 capacitors may be coupled in parallel to form a decoupling capacitor for a first voltage regulator, a second group of 10 capacitors may be coupled in parallel to form a decoupling capacitor for a second voltage regulator decoupling capacitor. The decoupling capacitors formed by the parallel combinations can provide suitable capacitance, ESR, and ESL values for the first and the second voltage regulators.

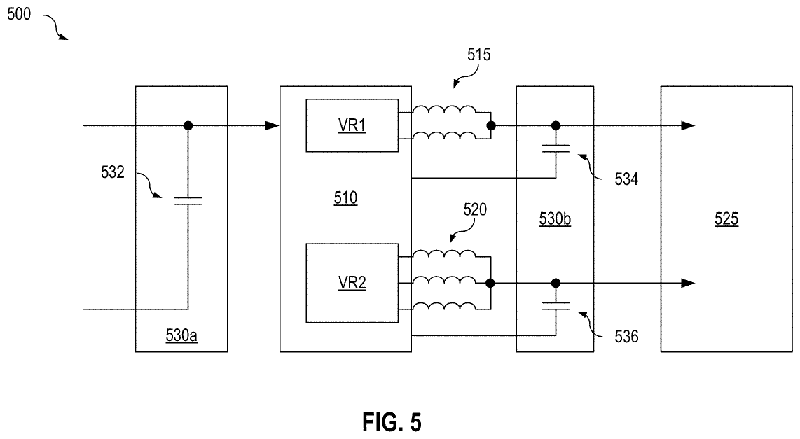

FIG. 5 is a simplified schematic diagram illustrating example circuit connections for an application of a configurable capacitance chip according to some aspects of the present disclosure. As shown in FIG. 5, an application of this configurable capacitor chip may be a dual channel voltage regulator (VR) 500 having a capacitor for each output.

Referring to FIG. 5, the dual channel voltage regulator may include a voltage regulator circuit 510 having a first voltage regulator VR1 and a second voltage regulator VR2. The first voltage regulator VR1 may generate an output current through a first set of inductors 515 to a load 525. The second voltage regulator VR2 may generate an output current through a second set of inductors 520 to the load 525. The configurable capacitance chip 530a, 530b according to the present disclosure may be configured to provide an input capacitor 532 and output capacitors 534, 536 for the voltage regulator circuit 510.

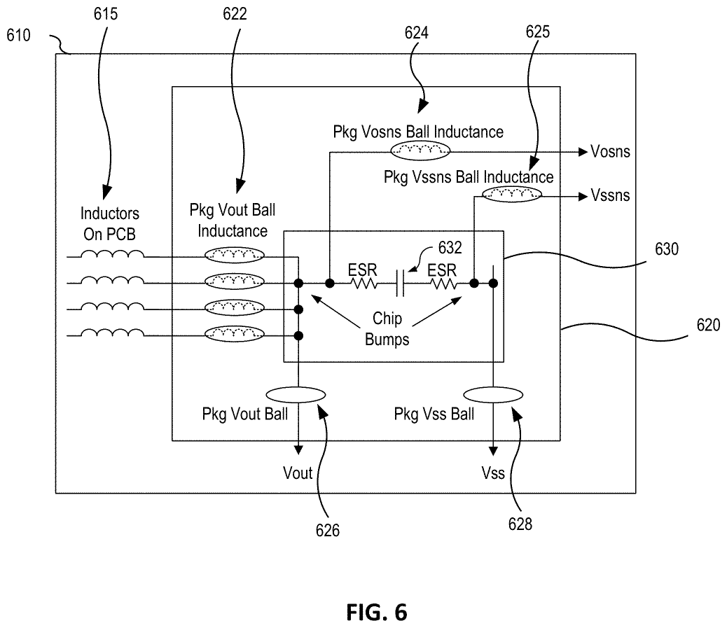

Printed circuit wiring and solder connections to electronic packages contribute parasitic inductances to a circuit. According to some aspects of the present disclosure, the package ball inductance may be incorporated into the output inductor of a circuit, for example a voltage regulator circuit. FIG. 6 is a simplified schematic diagram illustrating an example of some parasitic inductances of an electronic package according to some aspects of the present disclosure.

Referring to FIG. 6, an electronic package 620 may be mounted on the PCB 610 and electrically connected to the PCB 610 via package balls as previously described. A configurable capacitance chip 630 may be mounted within the electronic package 620 via chip bumps as previously described. A voltage regulator circuit (not shown) may include inductors 615 on a PCB 610. The inductors may be, for example, but not limited to, discrete component inductors, inductor traces formed on a surface of the PCB 610, inductor traces integrated within multiple layers of the PCB 610, etc.

One or more package balls 622 per inductor may be included as part of each of the PCB inductors 615. Incorporating the package ball inductance with the PCB inductors can reduce the effective ESL and ESR of the capacitor 632 affecting the control loop by sensing the output voltage via the Vosns package ball 624 as shown. Similarly, incorporating the package ball inductance with the PCB inductors can reduce the effective ESL and ESR of the capacitor 632 by sensing the voltage via the Vssns package ball 625. The Vout and Vss connections for the voltage regulator circuit may be brought out via the package Vout ball 626 and the package Vss ball 628. The Vout connection via the package Vout ball 626 may similarly reduce the output ripple by reducing the effective ESR and ESL of the capacitor 632.

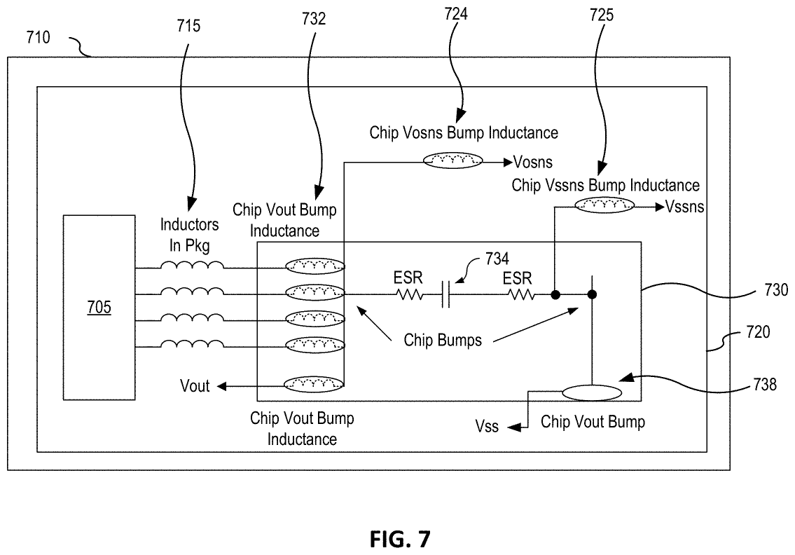

In some embodiments one or more inductors may be integrated within the electronic package substrate. FIG. 7 is a simplified schematic diagram illustrating another example of some parasitic inductances of an electronic package according to some aspects of the present disclosure. Referring to FIG. 7, a configurable capacitance chip 730 may be mounted within the electronic package 720 via chip bumps as previously described. The electronic package 720 may be mounted on a PCB 710 via package balls as previously described. A voltage regulator circuit 705 may be an integrated circuit included in the electronic package 720. The voltage regulator circuit 705 may be mounted within the electronic package 720 via chip bumps as previously described. Output inductors 715 for the voltage regulator circuit 705 may be, for example, but not limited to, discrete component inductors, embedded (or integrated) inductors formed by the metal traces on a single layer of the substrate of the electronic package 720 (or PCB) or within multiple layers of the electronic package substrate (or PCB), etc.

One or more chip bumps 732 per inductor may be included as part of each of the output inductors 715. Incorporating the chip bump inductance with the output inductors 715 can reduce the effective ESL and ESR of the capacitor 734 affecting the control loop by sensing the output voltage via the Vosns chip bump 724 and the Vssns chip bump 725 as shown. The Vout and Vss connections for the voltage regulator circuit may be brought out via the Vout chip bump 732 and the Vss chip bump 738.

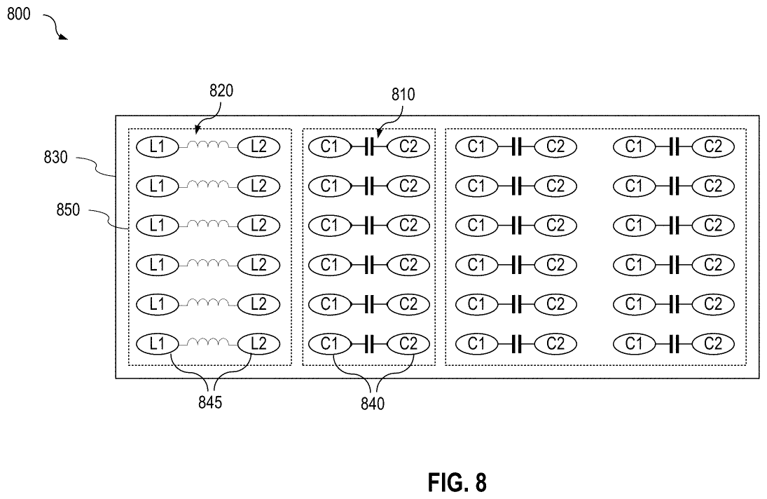

In accordance with some aspects of the present disclosure, various embodiments of the configurable capacitance chip may include additional configurable components such as resistors and inductors. FIG. 8 is a diagram illustrating a representative example of a configurable capacitance-inductance chip 800 according to some aspects of the present disclosure. Referring to FIG. 8, the configurable capacitance-inductance chip 800 may include a plurality of capacitors 810 and a plurality of inductors 820 fabricated on a first surface of a substrate 830. Each capacitor 810 and each inductor 820 may be electrically connected to a pair of contacts 840, 845, respectively, fabricated on the first surface of the substrate 830. The contacts 840, 845 fabricated on the first surface of the substrate 830 may be referred to herein as chip bumps. The chip bumps may be, for example, solder bumps.

The bumps may be fabricated similarly to the bumps as described with respect to FIG. 1. Also, as described with respect to FIG. 1, in some implementations, the capacitors 810 and the inductors 820 may be grouped into banks 850. In some implementations, the capacitors 810 and the inductors 820 may not be grouped into banks. In some implementations, the configurable capacitance-inductance chip 800 may include one or more voltage sense terminals Vosns and Vssns as described with respect to FIG. 3.

In some embodiments, a range of capacitance for each integrated capacitor can be between 10 and 10,000 nanofarads, in another embodiment can be between 50 and 5,000 nanofarads and in one embodiment between 50 and 500 nanofarads. In some embodiments, multiple capacitor 810 may be combined to provide larger or smaller capacitance values.

In some embodiments a range of inductance for each integrated inductors can be between 1 picohenry and 100 nanohenrys, in another embodiment can be between 100 picohenrys and 10 nanohenrys and in one embodiment between 1 and 5 nanohenrys.

It should be appreciated that FIG. 8 is a stylized representation of the configurable capacitance-inductance chip according to some aspects of the present disclosure, and is provided for ease of explanation. The figure is not meant to illustrate representative dimensions of any elements of the configurable capacitance-inductance chip. Further, the number of illustrated capacitors and inductors are merely representative and does not limit the number of capacitors and inductors or their relative placement provided by various embodiments. While the capacitor contacts 840 are labeled C1 and C2 and may be connected to Vout and/or Vss, or may be connected to other points in a circuit. The labels are merely representative and are not to be construed as requiring the capacitor contacts 840 to be connected to any specific voltages.

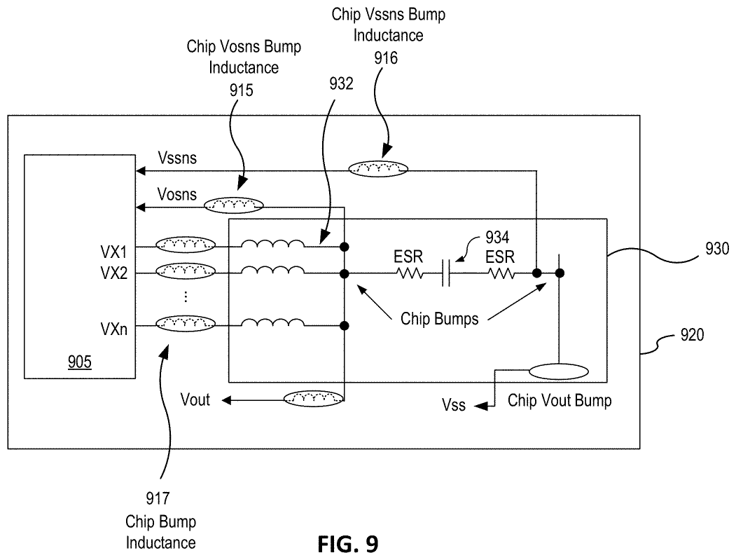

FIG. 9 is a simplified schematic diagram illustrating an example application of configurable capacitance-inductance chip according to some aspects of the present disclosure. Referring to FIG. 9, a configurable capacitance-inductance chip 930 may be mounted within the electronic package 920 via chip bumps as previously described. The electronic package 920 may be mounted on a PCB via package balls as previously described. A voltage regulator circuit 905 may be an integrated circuit included in the electronic package 920. The voltage regulator circuit 905 may be mounted within the electronic package 920 via chip bumps as previously described. In some implementations, the configurable capacitance-inductance chip and the voltage regulator circuit may be mounted directly to the PCB via the chip bumps.

Output inductors and capacitors for the voltage regulator circuit 905 may be provided by the inductors 932 and capacitors 934 of the configurable capacitance inductance chip 930. In some implementations, one or more chip bumps 917 per inductor may be included as part of each of the output inductors 932. Incorporating the chip bump 917 inductance with the output inductors 932 can reduce the effective ESL and ESR of the capacitor 934 affecting the control loop by sensing the output voltage via the Vosns chip bump 915 and the voltage Vss via the Vssns chip bump 916 as shown.

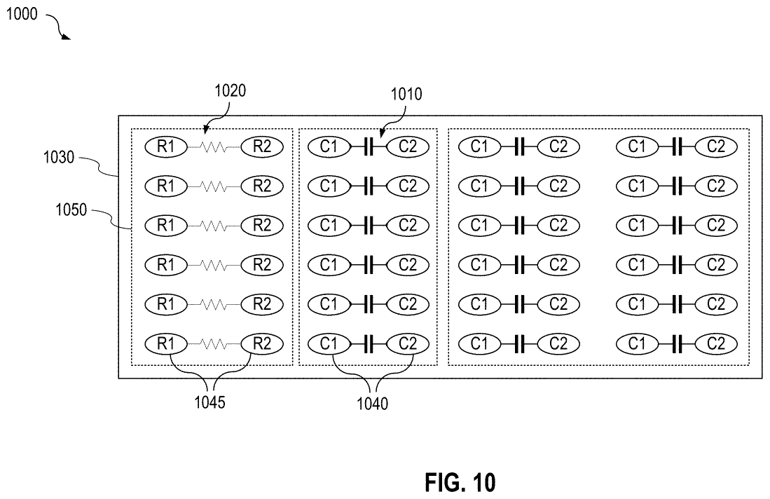

FIG. 10 is a diagram illustrating a representative example of a configurable capacitance-resistance chip 1000 according to some aspects of the present disclosure. Referring to FIG. 10, the configurable capacitance-resistance chip 1000 may include a plurality of capacitors 1010 and a plurality of resistors 1020 fabricated on a first surface of a substrate 1030. Each capacitor 1010 and each resistors 1020 may be electrically connected to a pair of contacts 1040, 1045, respectively, fabricated on the first surface of the substrate 1030. The contacts 1040, 1045 fabricated on the first surface of the substrate 1030 may be referred to herein as chip bumps. The chip bumps may be, for example, solder bumps.

The bumps may be fabricated similarly to the bumps as described with respect to FIG. 1. Also, as described with respect to FIG. 1, in some implementations, the capacitors 1010 and the resistors 1020 may be grouped into banks 1050. In some implementations, the capacitors 1010 and the resistors 1020 may not be grouped into banks. In some implementations, the configurable capacitance-resistance chip 1000 may include one or more voltage sense terminals Vosns and Vssns as described with respect to FIG. 3

In some embodiments, a range of capacitance for each integrated capacitor can be between 10 and 10,000 nanofarads, in another embodiment can be between 50 and 5,000 nanofarads and in one embodiment between 50 and 500 nanofarads. In some embodiments, multiple capacitors 1010 may be combined to provide larger or smaller capacitance values.

In some embodiments, a range of resistance for each integrated resistor can be between 50 ohms and ten thousand ohms. Other resistance ranges may be possible. In some embodiments, multiple resistors 1020 may be combined to provide larger or smaller resistance values.

It should be appreciated that FIG. 10 is a stylized representation of the configurable capacitance-resistance chip according to some aspects of the present disclosure, and is provided for ease of explanation. The figure is not meant to illustrate representative dimensions of any elements of the configurable capacitance-resistance chip. Further, the number of illustrated capacitors and resistors are merely representative and does not limit the number of capacitors and resistors or their relative placement provided by various embodiments. The capacitor contacts 1040 are labeled C1 and C2 and may be connected to Vout and/or Vss, or may be connected to other points in a circuit. The labels are merely representative and are not to be construed as requiring the capacitor contacts 1040 to be connected to any specific voltages.

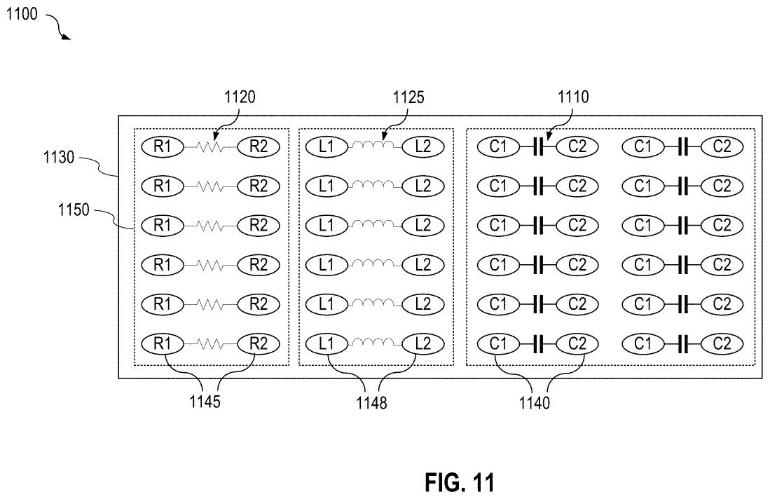

FIG. 11 is a diagram illustrating a representative example of a configurable capacitance-resistance-inductance chip 1100 according to some aspects of the present disclosure. Referring to FIG. 11, the configurable capacitance-resistance-inductance chip 1100 may include a plurality of capacitors 1110, a plurality of resistors 1120, and a plurality of inductors 1125 fabricated on a first surface of a substrate 1130. Each capacitor 1110, each resistor 1120, and each inductor 1125 may be electrically connected to a pair of contacts 1140, 1145, 1148, respectively, fabricated on the first surface of the substrate 1130.

The contacts 1140, 1145, 1148 fabricated on the first surface of the substrate 1130 may be referred to herein as chip bumps. The chip bumps may be, for example, solder bumps. The bumps may be fabricated similarly to the bumps as described with respect to FIG. 1. Also, as described with respect to FIG. 1, in some implementations, the capacitors 1110, the resistors 1120, and the inductors 1125 may be grouped into banks 1150. In some implementations, the capacitors 1110, the resistors 1120, and the inductors 1125 may not be grouped into banks. In some implementations, the configurable capacitance-resistance-inductance chip 1100 may include one or more voltage sense terminals Vosns and Vssns as described with respect to FIG. 3.

In some embodiments, a range of capacitance for each integrated capacitor can be between 10 and 10,000 nanofarads, in another embodiment can be between 50 and 5,000 nanofarads and in one embodiment between 50 and 500 nanofarads. In some embodiments, multiple capacitors 1110 may be combined to provide larger or smaller capacitance values.

In some embodiments, a range of resistance for each integrated resistor can be between 50 ohms and ten thousand ohms. Other resistance ranges may be possible. In some embodiments, multiple resistors 1120 may be combined to provide larger or smaller capacitance values.

In some embodiments a range of inductance for each integrated inductors can be between 1 picohenry and 100 nanohenrys, in another embodiment can be between 100 picohenrys and 10 nanohenrys and in one embodiment between 1 and 5 nanohenrys. In some embodiments, multiple inductors 1125 may be combined to provide larger or smaller inductance values.

It should be appreciated that FIG. 11 is a stylized representation of the configurable capacitance-resistance-inductance chip according to some aspects of the present disclosure, and is provided for ease of explanation. The figure is not meant to illustrate representative dimensions or any specific order of any elements of the configurable capacitance-resistance-inductance chip. Further, the number of illustrated capacitors, resistors, and inductors are merely representative and does not limit the number of capacitors, resistors, and inductors or their relative placement provided by various embodiments. In addition, while the capacitor contacts 1140 are labeled Vout and Vss in FIG. 11, the labels are merely representative and are not to be construed as requiring the capacitor contacts 1140 to be connected to Vout and Vss voltages.

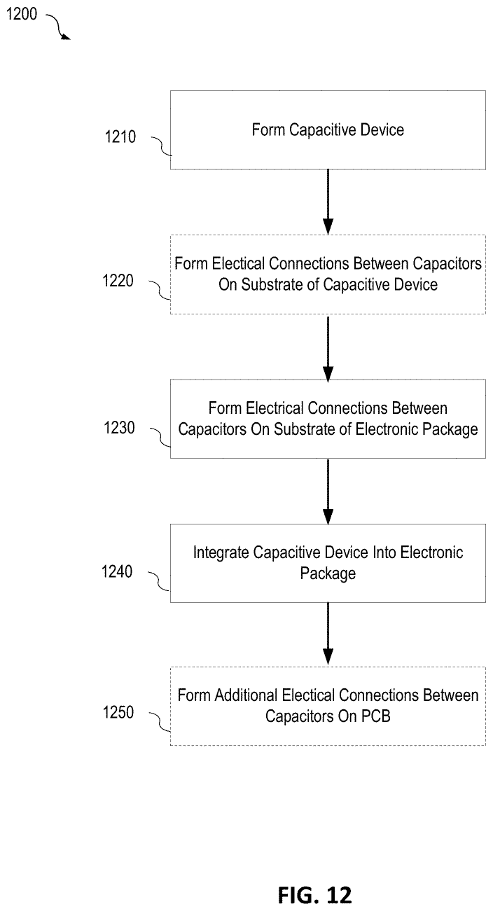

FIG. 12 is a flowchart illustrating an example of a method 1200 for making a configurable integrated circuit (IC) capacitive device according to some aspects of the present disclosure. Referring to FIG. 12, at block 1210, a capacitive device may be formed. The capacitive device may be fabricated using standard semiconductor processing techniques. A plurality of capacitors may be fabricated on a first surface of a substrate. Each capacitor may be electrically connected to a pair of contacts fabricated on the first surface of the substrate 120. The contacts fabricated on the first surface of the substrate may be referred to herein as chip bumps. The chip bumps may be, for example, solder bumps.

At optional block 1220, electrical connections between capacitors may be formed on the substrate of the capacitive device. In some embodiments, multiple capacitors may be combined to provide larger or smaller capacitance values. The combined capacitors may be referred to as capacitor banks. The capacitor banks may be formed, for example, by electrical connections fabricated on the second surface of the substrate.

At block 1230, electrical connections between capacitors may be formed on a substrate of an electronic package. The additional electrical connections may be fabricated as circuit traces on the substrate of the electronic package into which the capacitive device will be integrated. Conductive traces on the substrate of the electronic package may provide electrical connections between the chip bumps to configure the capacitors on the capacitive device.

At block 1240, the capacitive device may be integrated into the electronic package. Electrical connections may be formed between the substrate of the capacitive device and the substrate of the electronic package. For example, the solder bumps on the substrate of the capacitive device may be electrically connected to the conductive traces on the substrate of the electronic package. The electrical connections between the capacitors formed by the conductive traces on the substrate of the electronic package may form the desired capacitance values.

At optional block 1250, additional electrical connections between capacitors may be formed by conductive traces on the PCB to which the electronic package is attached. The electrical connections between the capacitors formed by the conductive traces on the PCB and conductive traces on the substrate of the electronic package may combine capacitors to form the desired capacitance values.

The specific operations illustrated in FIG. 12 provide a particular method for making a configurable integrated circuit (IC) capacitor according to an embodiment of the present disclosure. Other sequences of operations may also be performed according to alternative embodiments. For example, alternative embodiments of the present disclosure may perform the operations outlined above in a different order. Moreover, the individual operations illustrated in FIG. 12 may include multiple sub-operations that may be performed in various sequences as appropriate to the individual operation. Furthermore, additional operations may be added or removed depending on the particular applications.

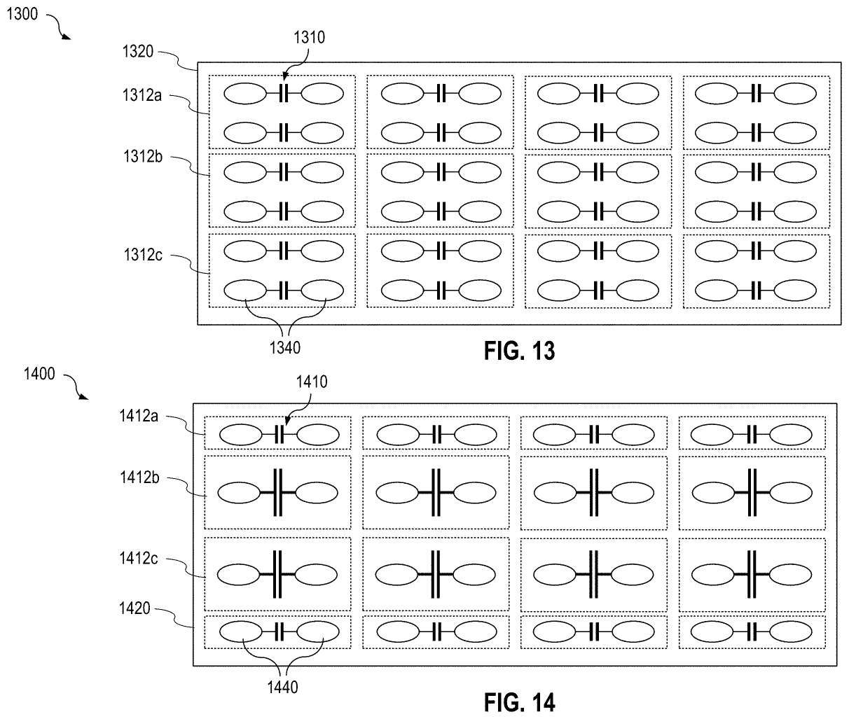

According to some aspects of the present disclosure, groups of capacitors may be formed on the semiconductor substrate of the configurable capacitance chip. The groups of capacitors may be referred to herein as “cells.” The cells may be of equal physical size and/or capacitance value with respect to the substrate occupied by a cell, or may be of unequal physical sizes and/or capacitance value. FIG. 13 is a diagram illustrating a representative example of a configurable capacitance chip 1300 having equal cell sizes with unequal capacitance values between cells according to some aspects of the present disclosure.

Referring to FIG. 13, the configurable capacitance chip 1300 may include a plurality of cells 1312a-1312b having integrally formed capacitors 1310 on the semiconductor substrate 1320. Each cell 1312a-1312c may include one or more integrally formed capacitors 1310, and each integrally formed capacitor 1310 in a respective cell may have a same capacitance value. For example, each integrally formed capacitor in a first cell 1312a may have a capacitance value of 100 nF, each integrally formed capacitor in a second cell 1312b may have a capacitance value of 200 nF, etc. More than one cell on the semiconductor substrate 1320 may have integrally formed capacitors 1310 having same capacitance values. For example, each integrally formed capacitor in a first cell 1312a and a third cell 1312c may have a capacitance value of 100 nF. The cells may be of equal size with respect to the of the substrate occupied by a cell.

Each integrally formed capacitor 1310 on the semiconductor substrate 1320 may include contact terminals 1340. The contact terminals 1340 may be available for electrical connection external to the configurable capacitance chip 1300. For example, circuit connections to the contact terminals 1340 of one or more of the integrally formed capacitors 1310 may be formed by external wiring traces on an integrated circuit package substrate (see, for example, FIG. 4) to which the configurable capacitance chip 1300 is mounted. In some cases, the external wiring traces on the integrated circuit package substrate may connect the contact terminals 1340 of two or more of the integrally formed capacitors 1310 in parallel or series to provide different values of capacitance.

In some cases, circuit connections to the contact terminals 1340 of one or more of the integrally formed capacitors 1310 may be formed by external wiring traces on a PCB to which the integrated circuit package (see, for example, FIG. 4) is mounted. In some cases, circuit connections to the contact terminals 1340 of one or more of the integrally formed capacitors 1310 may be formed by both external wiring traces on an integrated circuit package substrate to which the configurable capacitance chip 1300 is mounted and by external wiring traces on a PCB to which the integrated circuit package is mounted. The cells may be connected together in any configuration, for example, but not limited to, full or partial rows or columns, combinations of rows and columns, between cells of adjacent configurable capacitance chips, etc., to achieve desired capacitance values.

While FIG. 13 illustrates cells having two capacitors per cell, each cell may include any number of integrally formed capacitors. Further, each cell may include the same number or a different number of integrally formed capacitors. The capacitance values provided are merely exemplary for purposes of explanation. Cells of the configurable capacitance chip 1300 according to the present disclosure may have integrally formed capacitors having other capacitance values without departing from the scope of the present disclosure.

FIG. 14 is a diagram illustrating a representative example of a configurable capacitance chip 1400 having unequal cell sizes with unequal capacitance values between cells according to some aspects of the present disclosure. Referring to FIG. 14, the configurable capacitance chip 1400 may include a plurality of cells 1412a-1412b having integrally formed capacitors 1410 on the semiconductor substrate 1420. Each cell 1412a-1412b may include one or more integrally formed capacitors 1410, and each integrally formed capacitor 1410 in a respective cell may have a different capacitance value. For example, each integrally formed capacitor in a first cell 1412a may have a capacitance value of 100 nF, each integrally formed capacitor in a second cell 1412b may have a capacitance value of 200 nF, etc. More than one cell on the semiconductor substrate 1420 may have integrally formed capacitors 1410 having same capacitance values. For example, each integrally formed capacitor in a second cell 1412b and a third cell 1412c may have a capacitance value of 200 nF. The cells may be of unequal physical size with respect to the of the substrate area occupied by a cell. Cells having equal numbers of integrally formed capacitors having same capacitance values may have equal physical size with respect to the of the substrate area occupied by a cell.

Each integrally formed capacitor 1410 on the semiconductor substrate 1420 may include contact terminals 1440. The contact terminals 1440 may be available for electrical connection external to the configurable capacitance chip 1400. For example, circuit connections to the contact terminals 1440 of one or more of the integrally formed capacitors 1410 may be formed by external wiring traces on an integrated circuit package substrate (see, for example, FIG. 4) to which the configurable capacitance chip 1400 is mounted. In some cases, the external wiring traces on the integrated circuit package substrate may connect the contact terminals 1440 of two or more of the integrally formed capacitors 1410 in parallel or series to provide different values of capacitance. In some cases, the wiring traces forming the connections may be on the configurable capacitance chip 1400.

In some cases, circuit connections to the contact terminals 1440 of one or more of the integrally formed capacitors 1410 may be formed by external wiring traces on a PCB to which the integrated circuit package (see, for example, FIG. 4) is mounted. In some cases, circuit connections to the contact terminals 1440 of one or more of the integrally formed capacitors 1410 may be formed by both external wiring traces on an integrated circuit package substrate to which the configurable capacitance chip 1400 is mounted and by external wiring traces on a PCB to which the integrated circuit package is mounted. The cells may be connected together in any configuration, for example, but not limited to, full or partial rows or columns, combinations of rows and columns, between cells of adjacent configurable capacitance chips, etc., to achieve desired capacitance values.

While FIG. 14 illustrates cells having one capacitor per cell, each cell may include any number of integrally formed capacitors. Further, each cell may include the same number or a different number of integrally formed capacitors. The capacitance values provided are merely exemplary for purposes of explanation. Cells of the configurable capacitance chip 1400 according to the present disclosure may have integrally formed capacitors having other capacitance values without departing from the scope of the present disclosure.

In some implementations, multiple configurable capacitance chips in a semiconductor package may be interconnected such that various values of capacitance can be achieved. In some implementations, multiple configurable capacitance chips may be arranged in different orientations with respect to each other in a semiconductor package. The different orientations may permit interconnection of the configurable capacitance chips such that various values of capacitance can be achieved. For example, adjacent configurable capacitance chips may be rotated to permit interconnections between the configurable capacitance chips.

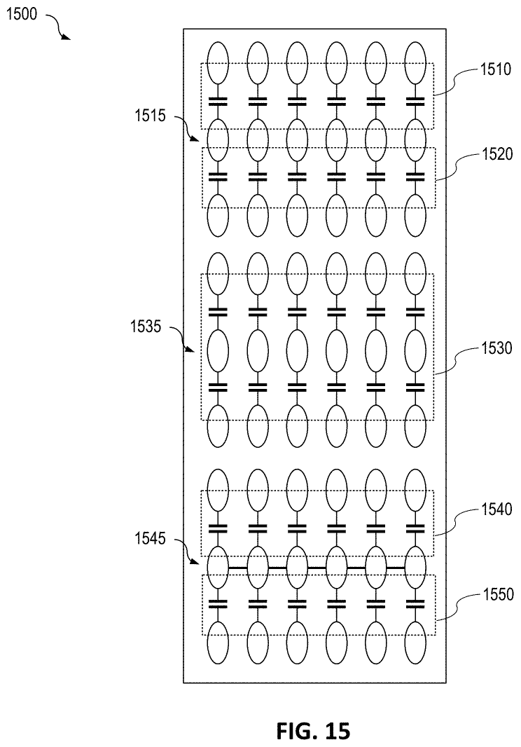

In some implementations, connections may be shared between integrally formed capacitors on a configurable capacitance chip. FIG. 15 is a diagram illustrating a representative example of a configurable capacitance chip 1500 having shared connections, for example, but not limited to, ground connections, between adjacent cells according to some aspects of the present disclosure. As shown in FIG. 15, integrally formed capacitors in a first cell 1510 may share one or more connections 1515 with integrally formed capacitors in a second cell 1520. In some implementations, a shared connection 1535 may be common to all the capacitors in one cell, for example, a third cell 1530. In still other implementations, a shared connection 1545 may be a common to all the capacitors in two cells, for example a fourth cell 1540 and a fifth cell 1550.

Each integrally formed capacitor in a respective cell may have the same capacitance value. The integrally formed capacitors in different cells may have different capacitance values. For example, referring to FIG. 15, each integrally formed capacitor in the first cell 1510 may have a capacitance value of 100 nF, each integrally formed capacitor in the second cell 1520 may have a capacitance value of 200 nF, and each integrally formed capacitor in the third cell 1530 may have a capacitance value of 300 nF. In some implementations, integrally formed capacitors in adjacent cells may have the same values. For example, each integrally formed capacitor in the fourth cell 1540 may have a capacitance value of 400 nF, and each integrally formed capacitor in the fifth cell 1550 may have a capacitance value of 400 nF.

According to some aspects of the present disclosure, copper pillar technology may be utilized to form electrical connections between a configurable capacitance chip and an electronic package substrate or PCB. Contact terminals for the integrally formed capacitors may be formed from metal layers on the semiconductor substrate of the configurable capacitance chip. Copper pillars formed between common contact terminals of the integrally formed capacitors can provide additional bonding surfaces for forming electrical connections to the configurable capacitance chip. The copper pillars may be formed over a passivation layer to connect the common contact terminals of the integrally formed capacitors.

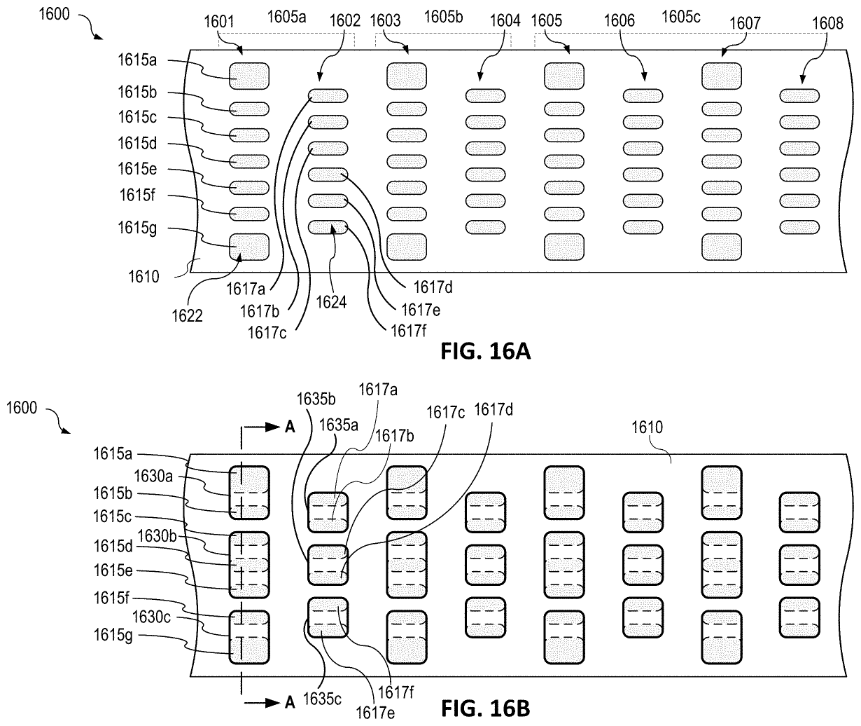

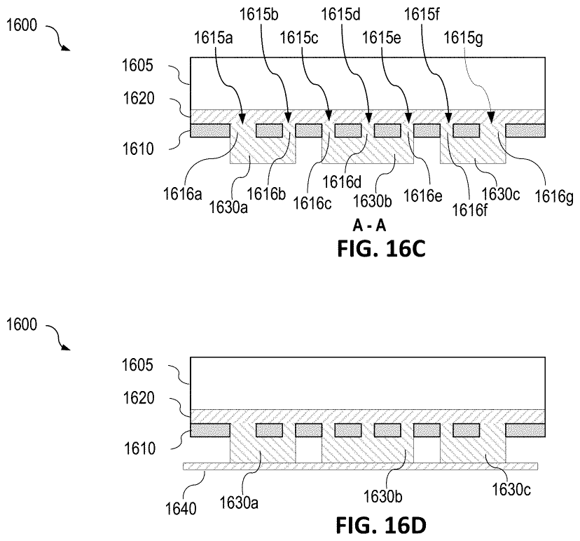

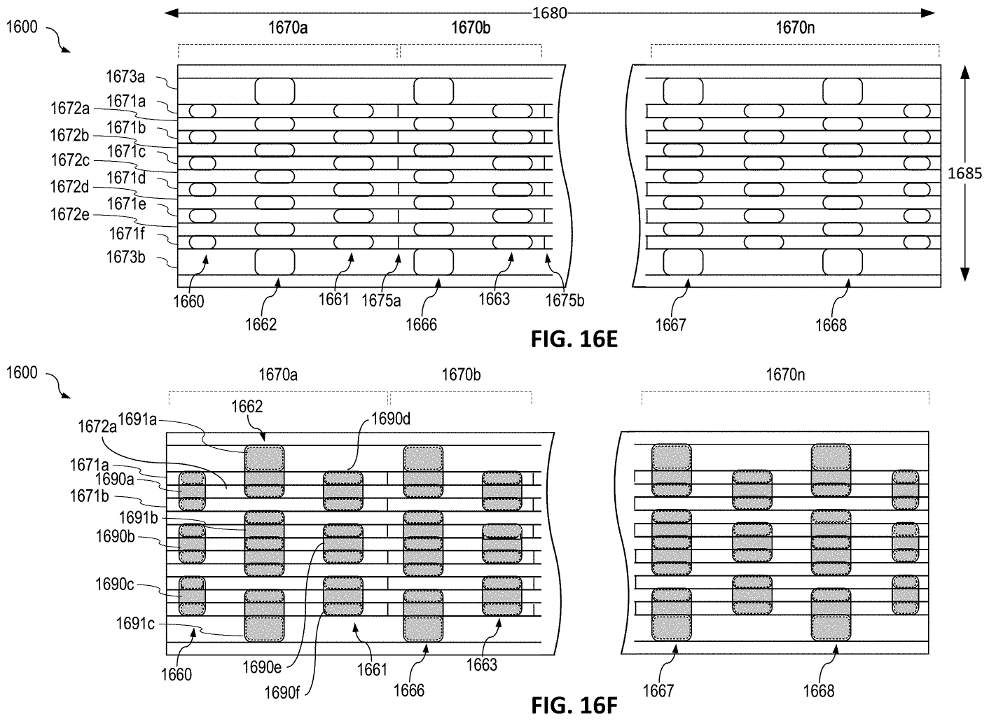

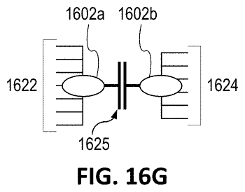

FIG. 16A is a diagram illustrating a representative example of a configurable capacitance chip 1600 showing a passivation layer 1610 according to some aspects of the present disclosure. FIG. 16A illustrates three cells 1605a-1605c, each cell containing one integrally formed capacitor that is made up of a plurality of smaller interconnected integrally formed capacitors. FIG. 16G is a simplified schematic diagram illustrating an example of an integrally formed capacitor of FIG. 6A according to some aspects of the present disclosure. In some implementations, the one integrally formed capacitor may be a single capacitive structure having a plurality of parallel interconnects, as described in more detail below.

Referring to FIG. 16G, the capacitor 1625 may represent a plurality of integrally formed capacitors that may be combined to form the capacitor 1625 having a combined capacitance value of the plurality of integrally formed capacitors. Each of the plurality of integrally formed capacitors may include a pair of contact terminals collectively represented as contact terminals 1602a, 1602b. The contact terminals 1602a, 1602b may be formed on the substrate and may form electrical connections to the integrally formed capacitors. At least one of the pair of contact terminals 1602a, 1602b may include secondary terminals 1622, 1624 connected in parallel to the contact terminal 1602a, 1602b. In some implementations, not every secondary terminal in each group of secondary terminals 1622, 1624 may be connected to every other secondary terminal in the group. In some implementations, the secondary terminals may be formed as a conductive strip extending from each of the contact terminals 1602a, 1602b. Interconnections may be formed to couple the secondary terminals 1622, 1624 to an opposite surface of the substrate from the surface on which the capacitors are formed.

Referring again to FIG. 16A, the passivation layer 1610 may be processed, for example, by etching or another method, to provide openings 1615a-1615g, 1617a-161f in the passivation layer 1610. The openings may correspond to the interconnections connecting to the underlying secondary terminals 1622, 1624 (see FIG. 16G) of the capacitor 1625. For example, the openings 1615a-1615g may correspond to the interconnections connecting to the underlying secondary terminals 1622 (see FIG. 16G) which may be, for example, terminals that will be connected to a ground electrical potential, referred to herein as negative terminals of the capacitors, and openings 1617a-161f may correspond to the interconnections connecting to the underlying secondary terminals 1624 that will be connected to a different electrical potential than ground, referred to herein as positive terminals of the capacitors.

Thus, each opening 1615a-1615g in the column 1601 may correspond to secondary terminals 1622 of the capacitor 1625 formed in the first cell 1605a to be connected to the negative terminal of the capacitor and each opening 1617a-1617f in column 1602 may correspond to secondary terminals 1624 to be connected to the positive terminal of the capacitor. Each opening in the column 1603 may correspond to secondary terminals of the capacitor formed in the second cell 1605b to be connected to the negative terminal of the capacitor and each opening in column 1604 may correspond to secondary terminals to be connected to the positive terminal of the capacitor. Similarly, each opening in the columns 1605 and 1607 may correspond to secondary terminals of the capacitor formed in the third cell 1605c to be connected to the negative terminal of the capacitor and each opening in columns 1606 and 1608 may correspond to secondary terminals to be connected to the positive terminal of the capacitor.

FIG. 16B is a diagram illustrating a representative example of the configurable capacitance chip 1600 of FIG. 16A showing copper pillars forming connections between a plurality of integrally formed capacitors in a cell, according to some aspects of the present disclosure. The copper pillars can provide multiple parallel interconnects to the capacitor reduce effective series inductance (ESL) and effective series resistance (ESR), which can be especially beneficial for power supply applications that have relatively high current with transients. As shown in FIG. 16B, copper pillar technology may be utilized to form copper pillars to provide electrical connections to the contact terminals of the integrally formed capacitors in each cell. For example, a copper pillar 1630a may be formed to electrically connect the negative contact terminals underlying openings 1615a and 1615b, a copper pillar 1630b may be formed to electrically connect the negative contact terminals underlying openings 1615c-1615e, and a copper pillar 1630c may be formed to electrically connect the negative contact terminals underlying the openings 1615f and 1615g. Similarly, a copper pillar 1635a may be formed to electrically connect the positive contact terminals underlying the openings 1617a and 1617b, a copper pillar 1635b may be formed to electrically connect the positive contact terminals underlying the openings 1617c and 1617d, and a copper pillar 1635c may be formed to electrically connect the positive contact terminals underlying the openings 1617e and 1617f. The copper pillars in each column may subsequently be coupled to conductive traces formed, for example, on a substrate of an IC package or a PCB, thereby electrically connecting each of the secondary terminals (e.g., secondary terminals 1622, 1624 in FIG. 16G) in a same column to a same electrical potential.

FIG. 16C is a diagram illustrating a cross sectional view along the section line A-A of the configurable capacitance chip in FIG. 16B according to some aspects of the present disclosure. As shown in FIG. 16C, copper extending regions 1616a-1616g may be formed through openings 1615a-1615g and copper pillars 1630a-1630c may form at least a portion of the copper extending regions 1616a-1616g that extend through the openings 1615a-1615g in the passivation layer 1610. In the example of FIG. 16C, the copper pillars 1630a-1630c may connect the underlying negative contact terminals of a plurality of integrated capacitors.

FIG. 16D is a diagram illustrating an example of a circuit trace 1640 connecting the copper pillars 1630a-1630c together according to some aspects of the present disclosure. The circuit trace 1640 may be, for example, a circuit trace on an electronic package substrate or PCB, configured to electrically connect the copper pillars 1630 that are each electrically connected to grounded contact terminals of separate capacitors. Thus, each of the underlying negative terminals of the capacitor in a cell and each of the underlying positive terminals of the capacitor in the cell may be electrically coupled. In embodiments where openings 1615 are too small to form external connections with an external structure (e.g., to a PCB, etc.), the copper pillars 1630 can provide larger contact regions that are suitable for forming connections to external PCBs, etc.

The one or more metal layers 1620 forming the contact terminals (e.g., the secondary terminals 1622, 1624) are represented as a region in FIGS. 16C, 16D and may be formed from copper or a combination of copper and one or more other materials. The one or more metal layers 1620 may each have a thickness in a range of about 0.5-5.0 μm and may be separated by respective dielectric layers. In some embodiments the one or more metal layers 1620 may include one or more redistribution layers. The passivation layer 1610 may be formed from polyimide or another material and may have a thickness in a range of about 0.5-1.0 μm. The passivation layer 1610 may provide a protective insulating layer over the integrally formed capacitors and contact terminals. The copper pillars 1630 may be formed from copper or a combination of copper and one or more other materials. The copper pillars 1630 may have a thickness in a range of about 5-75 μm.

FIG. 16E is a diagram illustrating an example of interconnections that can be formed between terminals of integrally formed capacitors of FIG. 16A according to some aspects of the present disclosure. Referring to FIG. 16E, each cell 1670a, 1670b, 1670n may include one capacitive element. The capacitive element may be formed by a plurality of individual integrally formed capacitors, or may be formed by a single capacitor having a plurality of parallel interconnects.

More specifically, in one embodiment a single capacitor may be formed in region 1670a and may have a plurality of positive terminal interconnect regions defined by passivation openings in columns 1660 and 1661. The single capacitor may have a plurality of negative terminal interconnect regions defined by passivation openings in column 1662. In some embodiments the plurality of positive terminal interconnect regions in column 1660 can be coupled to the plurality of positive terminal interconnect regions in column 1661 by interconnections 1671a-1671f In some embodiments interconnections 1671a-1671f may comprise metal traces that extend in first direction 1680. Similarly, interconnections 1673a-1673b may connect one or more columns of negative terminal interconnect regions together, however in this embodiment there is only one column 1662 of negative terminal interconnects.

In further embodiments a plurality of capacitive elements may be formed in region 1670a. More specifically, in one embodiment a capacitor may be formed between each interconnection, that is for example, a capacitor may be formed between interconnect 1673a and 1671a and another capacitor can be formed between interconnects 1672a and 1671b, etc. One of skill in the art will appreciate that other suitable configurations of individual capacitors can be configured within region 1670a.

As illustrated in FIG. 16E, interconnections 1671a-1671f may comprise metal traces that extend linearly in a first direction 1680 and may be formed between the passivation openings in column 1660 and the passivation openings in column 1661. Interconnections 1671a-1671f may be coupled to the positive terminals of integrally formed capacitors in the first cell 1670a. The interconnections 1671a-1671f may extend within the first cell 1670a and terminate at the cell boundary 1675a. Similarly, interconnections can be coupled to the positive terminals of integrally formed capacitors in the second cell 1670b extend only within the second cell 1670b, i.e., they terminate at the cell boundaries 1675a, 1675b.

The interconnections 1672a-1672e and 1673a-1673b may comprise metal traces that extend linearly in the first direction 1680 and may be formed between the passivation openings in column 1662 and in column 1666. Interconnections 1672a-1672e and 1673a-1673b may be coupled to the negative terminals of the integrally formed capacitors in the first cell 1670a. For example, the interconnection 1672a may couple a passivation opening in column 1662 to a passivation opening in each of columns 1666, column 1667, and column 1668. The interconnection 1673a-1673b may have a width in a second direction 1685 that is less than, equal to, or greater than the width of the interconnections 1672a-1672e.

The interconnections coupling the positive connections through passivation openings and the interconnections coupling the negative connections through passivation openings may be disposed in an alternating manner in a second direction 1685, for example, a width direction, of the substrate. The interconnections 1671a-1671f, 1672a-1672e, 1673a-1673b, may be formed on the substrate before formation of the passivation layer 1610, and the passivation layer 1610 formed over the interconnections 1671a-1671f, 1672a-1672e, 1673a-1673b with openings formed in the passivation layer enabling electrical contact to be made to the interconnections.

FIG. 16F is a diagram illustrating an example of copper pillars formed between passivation openings of the configurable capacitance chip 1600 of FIG. 16E according to some aspects of the present disclosure. As illustrated in FIG. 16F, copper pillars 1690a-1690c may electrically couple positive interconnections in column 1660 and copper pillars 1690d-1690f may electrically couple positive interconnections in column 1661 in the first cell 1670a. Similarly, copper pillars 1691a-1691c may electrically couple the negative interconnections in column 1662 in the first cell 1670a. Similar electrical couplings may be formed by copper pillars in columns 1666, 1667, and 1668 in each of the cells. The copper pillars in each column may subsequently be electrically coupled to conductive traces, for example, on a an IC package substrate or PCB, as illustrated in FIG. 16D.

Due to the alternating arrangement of the interconnections 1671a-1671f, 1672a-1672e, 1673a-1673b, the copper pillars coupling the interconnections in each column may span an interconnection. For example, the copper pillar 1690a that couples positive interconnections 1671a and 1671b in column 1660 through passivation openings in the passivation layer 1610 may span the negative interconnect 1672a. An electrical connection between the copper pillar 1690a and the negative interconnect 1672a is not formed since the copper pillar 1690a is formed over the passivation layer 1610 where no opening is formed. Copper pillars similarly connect the other interconnections on the configurable capacitance chip 1600.

While particular embodiments of the present disclosure have been shown and described, these are merely for ease of explanation. Various changes in the form of the example embodiments, for example, but not limited to, embodiments having more or fewer integrally formed capacitors, more or fewer copper pillars, different orientations of configurable capacitance chips, etc., may be made without departing from the scope of present disclosure. For example, a plurality of integrally formed capacitors having secondary terminals may be arranged in a cell and each integrally formed capacitor in the cell may have copper pillars formed to connect secondary terminals. A plurality of such cells may be fabricated on the substrate of the configurable capacitance chip.

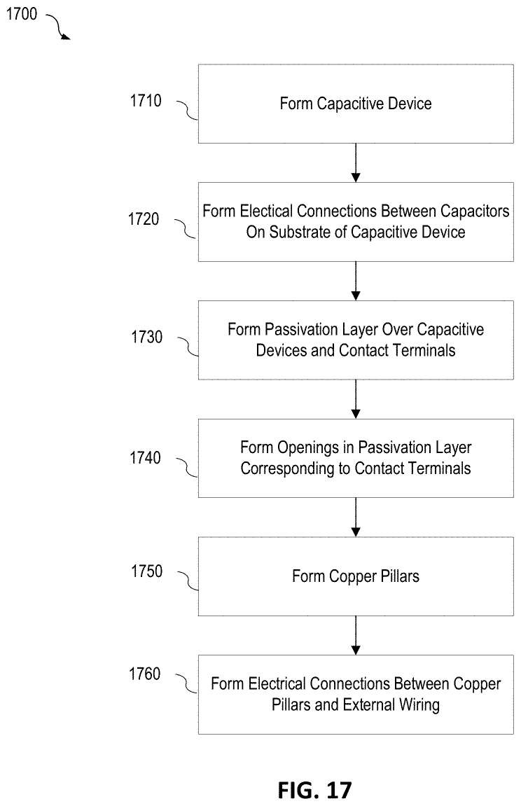

FIG. 17 is a flowchart illustrating an example of a method 1700 for making a configurable capacitance chip according to some aspects of the present disclosure. Referring to FIG. 17, at block 1710, a capacitive device may be formed. The capacitance chip may be fabricated using standard semiconductor processing techniques. A plurality of capacitors may be fabricated on a first surface of a substrate. Each capacitor may be electrically connected to a pair of contacts fabricated on the first surface of the substrate.

At block 1720, electrical connections may be formed on the substrate of the configurable capacitance chip. Metal layers may be provided to form multiple parallel contact terminals for each contact of a capacitor.

At block 1730, a passivation layer may be formed over the capacitors. A passivation layer may be formed over the plurality of capacitors and associated multiple parallel contact terminals. The passivation layer may be formed using standard semiconductor processing techniques. The passivation layer may be formed from polyimide, silicon oxide, silicon nitride, or another material and may have a thickness in a range of about 0.5-1.0 μm. The passivation layer may provide a protective insulating layer over the integrally formed capacitors and contact terminals.

At block 1740, openings may be formed in the passivation layer. The holes may be formed using standard semiconductor processing techniques. The holes in the passivation layer may correspond to the multiple parallel contact terminals for each contact of a capacitor.

At block 1750, copper pillars may be formed. Copper pillar technology may be utilized to form electrical connections between the multiple parallel contact terminals for each contact of a capacitor. The copper pillars may be formed over a passivation layer to connect common contact terminals of the integrally formed capacitors. The copper pillars 1630 may have a thickness in a range of about 5-75 μm.

At block 1760, electrical connections between the copper pillars and external wiring may be formed. The external wiring may be, for example, a circuit trace on an electronic package substrate or PCB, and may be configured to electrically connect the copper pillars that are electrically connected to the parallel contact terminals of the integrally formed capacitor. The holes may be formed using standard semiconductor processing techniques. The copper pillars can provide additional bonding surfaces for forming electrical connections between the contact terminals of the integrally formed capacitors of the configurable capacitance chip and the next higher level assembly, for example, an integrated circuit package or PCB.

The specific operations illustrated in FIG. 17 provide a particular method for making a configurable capacitance chip according to an embodiment of the present disclosure. Other sequences of operations may also be performed according to alternative embodiments. For example, alternative embodiments of the present disclosure may perform the operations outlined above in a different order. Moreover, the individual operations illustrated in FIG. 17 may include multiple sub-operations that may be performed in various sequences as appropriate to the individual operation. Furthermore, additional operations may be added or removed depending on the particular applications.

According to some aspects of the present disclosure, configurable capacitors in an integrated package are provided. As used below, any reference to a series of examples is to be understood as a reference to each of those examples disjunctively (e.g., “Examples 1-4” is to be understood as “Examples 1, 2, 3, or 4”).

Example 1 is a capacitance device, comprising: a semiconductor substrate; a capacitor disposed on the semiconductor substrate, the capacitor including first and second positive terminals and first and second negative terminals; a passivation layer formed over the capacitor, the first and second positive terminals and the first and second negative terminals, the passivation layer defining a first opening over the first positive terminal, a second opening over the second positive terminal, a third opening over the first negative terminal and a fourth opening over the second negative terminal; a first metallic bump disposed on the passivation layer and including first extending portions that extend through each of the first and second openings, electrically coupling the first positive terminal to the second positive terminal; and a second metallic bump disposed on the passivation layer and including second extending portions that extend through each of the third and fourth openings, electrically coupling the first negative terminal to the second negative terminal.

Example 2 is the capacitance device of example 1, wherein the first and the second positive terminals and the first and the second negative terminals each comprise parallel metallic traces extending across a surface of the semiconductor substrate.

Example 3 is the capacitance device of example(s) 1 or 2, wherein the first and second metallic bumps are copper pillars configured to be electrically and mechanically coupled to a substrate.

Example 4 is the capacitance device of example(s) 1-3, wherein the capacitor further comprises third and fourth positive terminals and third and fourth negative terminals.

Example 5 is the capacitance device of example(s) 1-4, wherein the passivation layer defines a fifth opening over the third positive terminal, a sixth opening over the fourth positive terminal, a seventh opening over the third negative terminal and an eighth opening over the fourth negative terminal.

Example 6 is the capacitance device of example(s) 1-5, wherein at least one pair of the plurality of integrally formed capacitors share one contact terminal of the pair of contact terminals.

Example 7 is the capacitance device of example(s) 1-6, further comprising a third metallic bump disposed on the passivation layer and including third extending portions that extend through each of the fifth and sixth openings, electrically coupling the third positive terminal to the fourth positive terminal; and a fourth metallic bump disposed on the passivation layer and including fourth extending portions that extend through each of the seventh and eighth openings, electrically coupling the third negative terminal to the fourth negative terminal

Example 8 is a device, comprising: a semiconductor substrate; a first capacitor disposed on the semiconductor substrate and electrically coupled between a first pair of metallic terminals and a second pair of metallic terminals, wherein the first and second pairs of metallic terminals are disposed on a first surface of the semiconductor substrate; a second capacitor disposed on the semiconductor substrate and electrically coupled between a third pair of metallic terminals and a fourth pair of metallic terminals, wherein the third and fourth pairs of metallic terminals are disposed on the first surface of the semiconductor substrate; a passivation layer disposed on the first surface of the semiconductor substrate and extending across at least the first, second, third and fourth pairs of metallic terminals; a pair of first openings defined by the passivation layer and a respective opening of the pair of first openings arranged over each of the pair of first metallic terminals; a pair of second openings defined by the passivation layer and a respective opening of the pair of second openings arranged over each of the pair of second metallic terminals; a pair of third openings defined by the passivation layer and a respective opening of the pair of third openings arranged over each of the pair of third metallic terminals; a pair of fourth openings defined by the passivation layer and a respective opening of the pair of fourth openings arranged over each of the pair of fourth metallic terminals; a first metallic bump disposed on the passivation layer and electrically coupling the pair of first metallic terminals together through the pair of first openings; a second metallic bump disposed on the passivation layer and electrically coupling the pair of second metallic terminals together through the pair of second openings; a third metallic bump disposed on the passivation layer and electrically coupling the pair of third metallic terminals together through the pair of third openings; and a fourth metallic bump disposed on the passivation layer and electrically coupling the pair of fourth metallic terminals together through the pair of fourth openings.

Example 9 is the device of example 8, wherein the first capacitor has a first capacitance and the second capacitor has a second capacitance, and wherein the first capacitance is different than the second capacitance.

Example 10 is the device of example(s) 8 or 9, wherein the first capacitor has a first capacitance and the second capacitor has a second capacitance, and wherein the first capacitance is equal to the second capacitance.

Example 11 is the device of example(s) 8-10, wherein the first, second, third and fourth pairs of terminals each comprise parallel metallic traces extending across the first surface of the semiconductor substrate.

Example 12 is the device of example(s) 8-11, wherein the first, second, third and fourth metallic bumps are copper pillars configured to be electrically and mechanically coupled to a substrate.

Example 13 is the device of example(s) 8-12, wherein the first and third pairs of metallic terminals are negative terminals of the first and second capacitors, respectively, and where the second and fourth pairs of metallic terminals are positive terminals of the first and second capacitors, respectively.

Example 14 is the device of example(s) 8-13, wherein at least one metallic terminal of the first pair of metallic terminals is electrically coupled to at least one metallic terminal of the third pair of metallic terminals.

Example 15 is a device, comprising: a semiconductor substrate; a first capacitor disposed on the semiconductor substrate and electrically coupled between a first terminal and a second terminal; a second capacitor disposed on the semiconductor substrate and electrically coupled between a third terminal and a fourth terminal; a passivation layer disposed across a first surface of the semiconductor substrate and defining a first opening formed over the first terminal, a second opening formed over the second terminal, a third opening formed over the third terminal and a fourth opening formed over the fourth terminal; a first metallic bump disposed on the passivation layer and electrically coupled to the first terminal and the third terminal through the first and the third openings, respectively; and a second metallic bump disposed on the passivation layer and electrically coupled to the second terminal and the fourth terminal through the second and the fourth openings, respectively.

Example 16 is the device of example 15, wherein the first capacitor has a first capacitance and the second capacitor has a second capacitance, and wherein the first capacitance is different than the second capacitance.

Example 17 is the device of example(s) 15 or 16, wherein the first capacitor has a first capacitance and the second capacitor has a second capacitance, and wherein the first capacitance is equal to the second capacitance.

Example 18 is the device of example(s) 15-17, wherein the first capacitor is coupled in parallel with the second capacitor via the first and second metallic bumps.

Example 19 is the device of claim example 15-18, wherein the first capacitor is coupled in series with the second capacitor via the first and second metallic bumps.

Example 20 is the device of example(s) 15-19, wherein the first and second metallic bumps are copper pillars configured to be electrically and mechanically coupled to a substrate.

The examples and embodiments described herein are for illustrative purposes only. Various modifications or changes in light thereof will be apparent to persons skilled in the art. These are to be included within the spirit and purview of this application, and the scope of the appended claims, which follow.

What is claimed is:

1. A capacitance device, comprising:
a semiconductor substrate;
a capacitor disposed on the semiconductor substrate, the capacitor including first and second positive terminals and first and second negative terminals;
a passivation layer formed over the capacitor, the first and second positive terminals and the first and second negative terminals, the passivation layer defining a first opening over the first positive terminal, a second opening over the second positive terminal, a third opening over the first negative terminal and a fourth opening over the second negative terminal;
a first metallic bump disposed on the passivation layer and including first extending portions that extend through each of the first and second openings, electrically coupling the first positive terminal to the second positive terminal; and
a second metallic bump disposed on the passivation layer and including second extending portions that extend through each of the third and fourth openings, electrically coupling the first negative terminal to the second negative terminal.

2. The capacitance device of claim 1 wherein the first and the second positive terminals and the first and the second negative terminals each comprise parallel metallic traces extending across a surface of the semiconductor substrate.

3. The capacitance device of claim 1 wherein the first and second metallic bumps are copper pillars configured to be electrically and mechanically coupled to a substrate.

4. The capacitance device of claim 1, wherein the capacitor further comprises third and fourth positive terminals and third and fourth negative terminals.

5. The capacitance device of claim 4, wherein the passivation layer defines a fifth opening over the third positive terminal, a sixth opening over the fourth positive terminal, a seventh opening over the third negative terminal and an eighth opening over the fourth negative terminal.

6. The capacitance device of claim 5, further comprising a third metallic bump disposed on the passivation layer and including third extending portions that extend through each of the fifth and sixth openings, electrically coupling the third positive terminal to the fourth positive terminal; and
a fourth metallic bump disposed on the passivation layer and including fourth extending portions that extend through each of the seventh and eighth openings, electrically coupling the third negative terminal to the fourth negative terminal.

7. The capacitance device of claim 6 wherein the first and third metallic bumps are arranged in a first column and the second and fourth metallic bumps are arranged in a second column.

8. A device comprising:
a semiconductor substrate;
a first capacitor disposed on the semiconductor substrate and electrically coupled between a first pair of metallic terminals and a second pair of metallic terminals, wherein the first and second pairs of metallic terminals are disposed on a first surface of the semiconductor substrate;
a second capacitor disposed on the semiconductor substrate and electrically coupled between a third pair of metallic terminals and a fourth pair of metallic terminals, wherein the third and fourth pairs of metallic terminals are disposed on the first surface of the semiconductor substrate;
a passivation layer disposed on the first surface of the semiconductor substrate and extending across at least the first, second, third, and fourth pairs of metallic terminals;
a pair of first openings defined by the passivation layer and a respective opening of the pair of first openings arranged over each of the pair of first metallic terminals;
a pair of second openings defined by the passivation layer and a respective opening of the pair of second openings arranged over each of the pair of second metallic terminals;
a pair of third openings defined by the passivation layer and a respective opening of the pair of third openings arranged over each of the pair of third metallic terminals;
a pair of fourth openings defined by the passivation layer and a respective opening of the pair of fourth openings arranged over each of the pair of fourth metallic terminals;
a first metallic bump disposed on the passivation layer and electrically coupling the pair of first metallic terminals together through the pair of first openings;
a second metallic bump disposed on the passivation layer and electrically coupling the pair of second metallic terminals together through the pair of second openings;
a third metallic bump disposed on the passivation layer and electrically coupling the pair of third metallic terminals together through the pair of third openings; and
a fourth metallic bump disposed on the passivation layer and electrically coupling the pair of fourth metallic terminals together through the pair of fourth openings.

9. The device of claim 8 wherein the first capacitor has a first capacitance and the second capacitor has a second capacitance, and wherein the first capacitance is different than the second capacitance.

10. The device of claim 8 wherein the first capacitor has a first capacitance and the second capacitor has a second capacitance, and wherein the first capacitance is equal to the second capacitance.

11. The device of claim 8 wherein the first, second, third and fourth pairs of terminals each comprise parallel metallic traces extending across the first surface of the semiconductor substrate.

12. The device of claim 8 wherein the first, second, third and fourth metallic bumps are copper pillars configured to be electrically and mechanically coupled to a substrate.

13. The device of claim 8 wherein the first and third pairs of metallic terminals are negative terminals of the first and second capacitors, respectively, and where the second and fourth pairs of metallic terminals are positive terminals of the first and second capacitors, respectively.

14. The device of claim 13 wherein at least one metallic terminal of the first pair of metallic terminals is electrically coupled to at least one metallic terminal of the third pair of metallic terminals.

15. A device comprising:
a semiconductor substrate;
a first capacitor disposed on the semiconductor substrate and electrically coupled between a first terminal and a second terminal;
a second capacitor disposed on the semiconductor substrate and electrically coupled between a third terminal and a fourth terminal;
a passivation layer disposed across a first surface of the semiconductor substrate and defining a first opening formed over the first terminal, a second opening formed over the second terminal, a third opening formed over the third terminal, and a fourth opening formed over the fourth terminal;
a first metallic bump disposed on the passivation layer and electrically coupled to the first terminal and the third terminal through the first and the third openings, respectively; and
a second metallic bump disposed on the passivation layer and electrically coupled to the second terminal and the fourth terminal through the second and the fourth openings, respectively.

16. The device of claim 15 wherein the first capacitor has a first capacitance and the second capacitor has a second capacitance, and wherein the first capacitance is different than the second capacitance.

17. The device of claim 15 wherein the first capacitor has a first capacitance and the second capacitor has a second capacitance, and wherein the first capacitance is equal to the second capacitance.

18. The device of claim 15 wherein the first capacitor is coupled in parallel with the second capacitor via the first and second metallic bumps.

19. The device of claim 15 wherein the first capacitor is coupled in series with the second capacitor via the first and second metallic bumps.

20. The device of claim 15 wherein the first and second metallic bumps are copper pillars configured to be electrically and mechanically coupled to a substrate.
